(19) United States
(12) Patent Application Publication
(10) Pub. No.: US 2003/0209323 A1
(43) Pub. Date: Nov. 13, 2003

(54) Production apparatus for manufacturing semiconductor device

(75) Inventor: Tsuyoshi Yokogaki, Kanagawa (JP)

Correspondence Address: McGinn & Gibb, PLLC, Suite 200, 8321 Old Courthouse Road, Vienna, VA, 22182-3817, US

(73) Assignee: NEC Electronics Corporation, Kawasaki (JP)

(21) Appl. No.: 10/427,918

(22) Filed: May 2, 2003

(30) Foreign Application Priority Data
May 7, 2002 (JP) 131477/2002

(51) Int. Cl. H01L 21/306; C23C 16/00

(52) U.S. Cl. 156/345.34; 118/715; 156/345.33

(57) ABSTRACT

The present invention discloses a production apparatus for manufacturing semiconductor device which comprises a vacuum processing chamber where film formation or etching is performed for a semiconductor wafer, a gas introducing part for introducing a process gas into the vacuum processing chamber, and a shower head for uniformly diffusing the introduced process gas, where a plate having a plurality of gas blowing holes for blowing the process gas on the semiconductor wafer are arranged and opened with uniform density is provided on the face of a shower head opposing the semiconductor wafer. Each of the gas blowing holes opened in the plate is a steeped hole having a large diameter hole part and a small diameter hole part, formed by varying the step location in response to the pressure distribution of the process gas within the shower head so as to make the amount of the gas blown from respective gas blowing holes uniform.

### BACKGROUND OF THE INVENTION

1. Field of the Invention

The present invention relates to a production apparatus for manufacturing semiconductor device, which apparatus carries out film formation or etching to a semiconductor wafer, and more particularly to an improvement on a shower head which blows a process gas upon the semiconductor wafer.

2. Description of the Related Art

As an apparatus for forming a thin film on a semiconductor wafer or an apparatus for carrying out etching process to the semiconductor wafer, a chemical vapor deposition apparatus, a plasma etching apparatus or the like has been used. Any of these manufacturing apparatuses is configured such that a process gas is jetted out perpendicular toward a major face of the semiconductor wafer through a large number of orifices opened in a shower head in order to perform film formation or etching by utilizing chemical reactions on the major face of the semiconductor wafer.

In FIG. 1 is shown a sectional view of a general schematic structure of a conventional film formation apparatus being a vacuum processing chamber of a single wafer type low-pressure vapor deposition apparatus. Namely, the apparatus comprises a wafer stage 4 for placing a semiconductor wafer 8, and a shower head 3 for blowing a process gas on the semiconductor wafer 8 are provided in a vacuum processing chamber 1, and a gas introducing part 2 for introducing the process gas. The shower head 3 includes a main head part 3M and a plate 9 attached to the main head part 3M such that the front surface 9F of the plate 9 faces to the semiconductor wafer 8 and that the back surface 9B of the plate 9 faces to the main head part 3M to form a space 10 between the back surface 9B of the plate and main head part 3M. The space 10 is connected to the gas introducing part 2. In the plate 9, a large number of gas blowing holes 5 are formed. The process gas supplied from the gas introducing part 2 is arranged to be blown perpendicular to the central part of the plate 9. Accordingly, the pressure of the process gas introduced to the shower head 3 is high in the vicinity of the central part of the plate 9 and decreases as one moves toward the peripheral part.

The shape of the conventional gas blowing holes 5 formed in the shower head 3 is either one of a straight hole, a step hole or a tapered hole as shown in sectional views (a), (b) and (c), respectively, of FIG. 2. Since these gas blowing holes 5 are made in identical size and shape in the same plate 9, if the gas blowing holes are arranged with uniform density, the amount of the process gas blown out from the shower head 3 onto the semiconductor wafer 8 is large at the gas blowing holes 5 distributed in the vicinity of the central part of the plate 9, and decreases as the gas blowing holes 5 are located away from the vicinity of the central part. Accordingly, the distribution of the amount of the process gas spouted from the shower head 3 to the semiconductor wafer 8 is non-uniform. As a result, film is formed thicker in the vicinity of the central par of the semiconductor wafer compared with in the peripheral part, failing to form a uniform film over the entire surface of the semiconductor wafer. Furthermore, although not shown, a similar problem occurs in an etching apparatus, and a uniform etching over the entire surface of the semiconductor wafer is not achievable.

Under these circumstances, in order to uniformize the amount of blowing of the process gas upon the semiconductor wafer, various ideas, such as making the hole diameter small in the vicinity of the central part of the plate and making the hole diameter large as one moves toward the peripheral part while keeping the distribution density of the gas blowing holes constant, or on the contrary, reducing the number of holes in the vicinity of the central part of the plate and increasing the number of the holes as one moves toward the peripheral part, while keeping the diameter of the gas blowing holes constant. However, a large number of drills have to be prepared in order to vary gradually the diameter of the holes, and the machining of gradually changing the diameter of the holes is not easy. At any rate, it leads to an increase in the processing labor hours or in the machining cost, and fails to be a general method of solution.

Moreover, a method of forming stepped holes in advance with uniform size in the whole area including the central part and the peripheral parts in the shower head, and means of controlling the flow of gas blowing by inserting hole opening pins in the stepped holes to adjust the positions of the stepped parts, has been disclosed in Japanese Patent Applications Laid Open, No. Hei 4-115531. However, this method requires preparation of various kinds of hole opening pins of different length, in addition to the machining of the stepped holes, and requires a considerable labor hours for attaching and detaching the hole opening pins, so that it is not a practical means.

### SUMMARY OF THE INVENTION

It is an object of the present invention to uniformize the thickness of the formed film or uniformize the etching amount for the semiconductor wafer, by making uniform amount of the blowing process gas, from the shower head toward the semiconductor wafer on the entire surface of the semiconductor wafer. For this purpose, the resistance of the gas blowing holes is varied by giving a different shape to each of a plurality of gas blowing holes opened in the plate with a uniform density, in order to obtain a uniform blowing amount of the process gas regardless of the position of the hole at the central part or the peripheral part of the shower head

According to one feature of the present invention, there is provided an production apparatus for manufacturing a semiconductor device which comprises a vacuum processing chamber where film formation or etching processing for a semiconductor wafer is performed, a gas introducing part for introducing a process gas into the vacuum processing chamber and a shower head for uniformly diffusing the introduced process gas. The shower head includes a plate which has a plurality of gas blowing holes for blowing the process gas on the semiconductor wafer; the gas blowing holes are arranged and opened with uniform density. Each of said gas blowing holes opened in the plate comprises a stepped hole which has a large diameter hole part and a small diameter hole part formed in such a way that the position of the step is varied in response to the pressure distribution of the process gas within the shower head in order to make the amount of the gas blowing from respective gas blowing holes is uniform.

Moreover, the gas blowing hole of stepped hole structure of the present invention may be arranged to be given varying resistances by adjusting the lengths of the large diameter hole part and the small diameter hole part, and the resistance of the gas blowing holes is adjusted.

Further, the shower head may include a main head part and the plate attached to the main head part such that the front surface of the plate faces to the semiconductor wafer and that the back surface of the plate faces to the main head part to form a space between the back surface of the plate and the main head part; the resistance of the gas blowing hole is varied corresponding to the pressure distribution in said space.

Furthermore, the resistance of the gas blowing hole at a portion of the space with high pressure of the process gas may be made high, and the resistance of the gas blowing hole at a portion of the space with low pressure of the process gas may be made low corresponding to the pressure distribution on the back surface the said plate. Moreover, the length of the large diameter hole part may be made short for the gas blowing hole located in the vicinity of the central part of the plate and the length of the large diameter hole part is made to increase gradually as one moves toward the peripheral part of the plate.

Moreover, an identical plate may be made to be usable for semiconductor wafers with different diameters.

### BRIEF DESCRIPTION OF THE DRAWINGS

The above-mentioned and other objects, features and advantages of this invention will become more apparent by reference to the following detailed description of the invention taken in conjunction with the accompanying drawings, wherein:

FIG. 1 is a sectional view showing a general structure of a conventional semiconductor device manufacturing apparatus;

FIG. 2 is a sectional view showing examples of the structure of the conventional gas blowing hole;

FIG. 3 is a plan view showing an example of arrangement and distribution of the gas blowing holes;

FIG. 4 is a schematic sectional view showing an embodiment in the production apparatus for manufacturing semiconductor device according to the present invention; and

FIG. 5 is a sectional view for describing the structure of the gas blowing holes of the shower head used in the embodiment of the present invention.

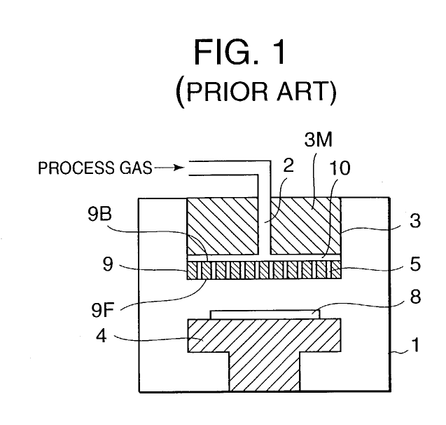

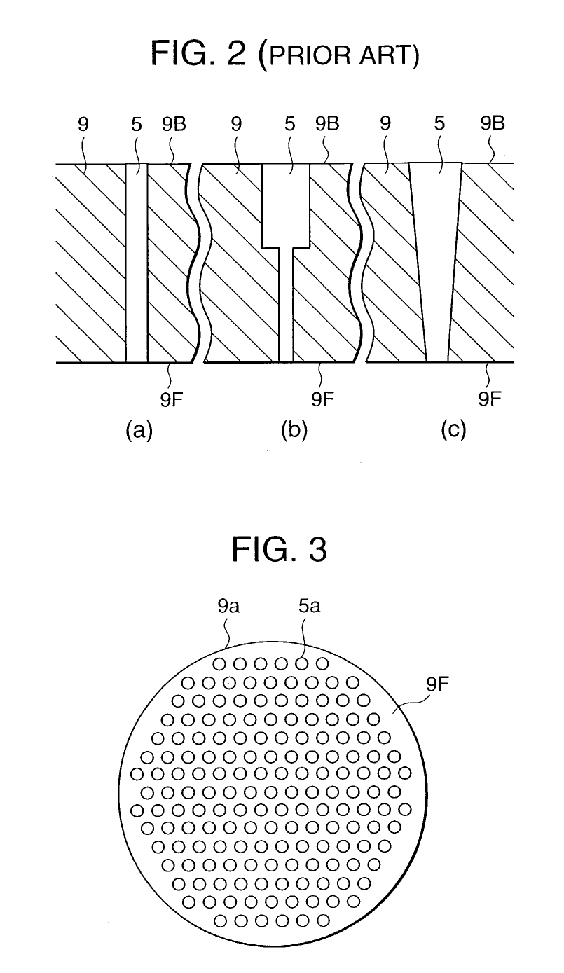

### DESCRIPTION OF THE PREFERRED EMBODIMENT

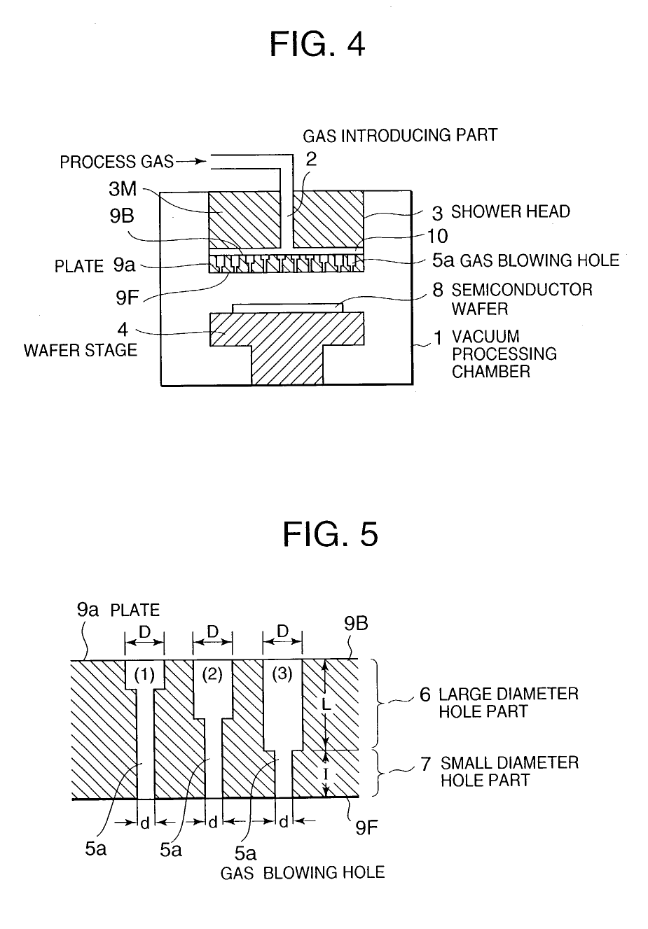

Referring to the drawings, an embodiment of the production apparatus for manufacturing semiconductor device according to the present invention will be described next. FIG. 4 is a sectional view showing a general structure of the production apparatus in the-embodiment of the present invention, and FIG. 5 is a drawing for showing the sectional view of the plate attached to the shower head used in the invention, and for describing the form of the blowing holes of the process gas opened in the plate.

First, referring to FIG. 4, the apparatus of the present invention comprises a wafer stage 4 for placing a semiconductor wafer 8, and a shower head 3 for blowing a process gas on the semiconductor wafer 8 are provided in a vacuum processing chamber 1, and a gas introducing part 2 for introducing the process gas. The shower head 3 includes a main head part 3M and a plate 9a attached to the main head part 3M such that the front surface 9F of the plate 9a faces to the semiconductor wafer 8 and that the back surface 9B of the plate 9a faces to the main head part 3M to form a space 10 between the back surface 9B of the plate and main head part 3M. The space 10 is connected to the gas introducing part 2. In the plate 9a, a large number of gas blowing holes 5a are formed. As shown in FIG. 3, the gas blowing holes 5a penetrated between the front surface 9F and the back surface 9B of the plate 9a are uniformly distributed in the plane figure of the plate 9a.

Next, referring to FIG. 5, the structure of the shower head which is the feature of the invention will be described. Each of the gas blowing holes 5a of the process gas opened in a plate 9a attached to the main head part 3M of the shower head 3 is a stepped hole, consisting of two steps, whose length (thickness of the plate 9a) is the sum of a length L of a large diameter hole part 6 with a diameter D, and a length l of a small diameter hole part 7 with a diameter d. That is, the plurality of blowing holes 5a including the large and small diameter hole parts 6, 7 are formed in the plate 9a itself such that their entire wall portions are made of the plate 9a. The process gas flows from the large diameter hole part 6 opened at the back surface 9B toward the small diameter hole part 7 opened at the front surface 9F. The resistance received by the process gas in passing through the hole is small in the large diameter hole part 6, and is large in the small diameter hole part 7. Moreover, it is the smaller for the larger length L of the large diameter hole part 6, and is the larger for the larger length l of the small diameter hole part 7. In other words, assuming that the pressure of the process gas supplied to respective holes from the space 10 is the same, the resistance received by the process gas passing through the blowing holes 5a is the highest for the hole (1) with the shortest length L, and decreases for the holes (2) and (3) in this order. As a result, the flow rate of the process gas that passes through the holes is the smallest for the hole (1), and increases for the holes (2) and (3) in this order.

The present invention is based on such a principle of operation, and is characterized in that the amount of gas blow from the gas blowing holes is uniformed by varying the resistance of the gas blowing holes 5a formed in the plate 9a, of the shower head, in which a plurality of gas blowing holes 5a of the stepped hole structure are distributively arranged. As shown in FIG. 4 and FIG. 5, the resistance of the gas blowing hole 5a is made large in the central part in the vicinity of the gas introducing part 2, and the resistance of the gas blowing hole 5a is made to decrease as one moves away from the gas introducing part 2 toward the peripheral part, by varying the length of the large diameter hole part 6 and the small diameter hole part 7 of the gas blowing holes 5a opened in the plate 9a of the shower head 3, to uniformize the amount of gas blow from the gas blowing holes 5a of the shower head 3.

To summarize, the production apparatus for manufacturing a semiconductor device according to the invention is constituted with the vacuum processing chamber 1 for forming a film on the semiconductor wafer 8, the gas introducing part 2 for introducing the process gas, the shower head 3 for uniformly diffusing the process gas and the wafer stage 4 for placing the semiconductor wafer 8 as the principal parts, as shown in FIG. 4. In addition, the shower head 3 is equipped with a plate 9a provided with gas blowing holes 5a of stepped hole structure having holes with. two steps, where the gas blowing hole 5a consists of the large diameter hole part 6 and the small diameter hole part 7, as shown in FIG. 5. The gas blowing hole 5a has a small length L for the large diameter hole part 6 in the vicinity of the gas introducing part 2, and the length L of the large diameter hole part 6 increases as one moves away from the gas introducing part 2.

Next, referring to FIG. 4 and FIG. 5, the operation of the present invention will be described. The process gas introduced from the gas introducing part 2 diffuses in the shower head 3, but its pressure is high in the vicinity of the gas introducing part 2 in the shower head 3, and decreases as one moves away from the gas introducing part 2. However, since the length of the large diameter hole part 6 of the gas blowing holes 5a is short in the central part of the plate 9a closer to the gas introducing part 2, the process gas is less easy to pass through the holes, whereas since the length of the large diameter hole part 6 of the gas blowing holes 5a is long and the resistance to the process gas decreases in the peripheral part of the plate as one moves away from the gas introducing part 2, the flow of the process gas is easy there.

Consequently, at a location close to the gas introducing part 2, the flow of the process gas is less easy due to a larger resistance of the gas blow-off holes 5a, although the gas pressure to the gas blowing holes 5a is high. On the other hand, at a location away from the gas introducing part 2, the flow of the process gas is easy due to small resistance of the gas blowing holes 5a, although the gas pressure to the gas blowing holes 5a is low there. As a result, it is possible to uniformize the amount of gas blown from respective gas blowing holes 5a.

As described in the. above, by employing the apparatus of this invention having an improvement in the shower head, it is possible to uniformize the amount of the process gas blown from the gas blowing holes. Accordingly, the distance between the shower head and the semiconductor wafer can be reduced which eliminates the use of more than necessary amount of the process gas, so that it is possible to cut down the amount of use of the process gas. Moreover, when the diameter of the semiconductor wafer is increased, the variation in the thickness of the formed film between the central part and the peripheral part of the wafer was particularly conspicuous according to the conventional method. Since, however, the use of the shower head of this invention eliminates such a variation, use of a shower head of the same design becomes possible regardless of the diameter of the wafer. Furthermore, in the conventional method, when the arrangement density of the blowing holes is constant, a large number of drills are required for machining because of a gradual change in the diameter of the blowing holes, but the machining can be accomplished using only two kinds of large and small dills in this invention.

As has been described in the above, since it is possible to blow the process gas from the shower head uniformly on the semiconductor wafer according to this invention, when a film is formed or etching is performed using the semiconductor device, uniform film formation on, or etching of, the semiconductor wafer becomes feasible.

Although the invention has been described with reference to a specific embodiment, this description is not meant to be construed in a limiting sense. Various modifications of the disclosed embodiment will become apparent to persons skilled in the art upon reference to the description of the invention. It is therefore contemplated that the appended claims cover any modifications or embodiments as fall within the true scope of the invention.

What is claimed is:

1. An production apparatus for manufacturing a semiconductor device comprising a vacuum processing chamber where film formation or etching processing for a semiconductor wafer is performed, a gas introducing part for introducing a process gas into said vacuum processing chamber and a shower head for uniformly diffusing the introduced process gas, said shower head including a plate having a plurality of gas blowing holes for blowing said process gas on said semiconductor wafer, said gas blowing holes being arranged and opened with uniform density wherein
each of said gas blowing holes opened in said plate comprises a stepped hole having a large diameter hole part and a small diameter hole part formed in such a way that the position of the step is varied in response to the pressure distribution of said process gas within said shower head in order to make the amount of the gas blowing from respective gas blowing holes is uniform.

2. The production apparatus as claimed in claim 1, wherein said gas blowing hole of stepped hole structure functions to change the resistance of said gas blowing hole by varying the length of said large diameter hole part and the length of said small diameter hole part.

3. The production apparatus as claimed in claim 1, wherein said shower head includes a main head part and said plate attached to said main head part such that the front surface of said plate faces to said semiconductor wafer and that the back surface of said plate faces to said main head part to form a space between said back surface of said plate and said main head part; the resistance of the gas blowing hole is varied corresponding to the pressure distribution in said space.

4. The production apparatus claimed in claim 3, wherein said resistance of said gas blowing hole at a portion of said space with high pressure of said process gas is made high, and said resistance of said gas blowing hole at a portion of said space with low pressure of the process gas is made low corresponding to the pressure distribution on said back surface of said plate.

5. The production apparatus as claimed in claim 4, wherein the length of said large diameter hole part is made short for the gas blowing hole located in the vicinity of the central part of said plate and the length of said large diameter hole part is made to increase gradually as one moves toward the peripheral part of said plate.

6. The production apparatus as claimed in claim 5, wherein the same plate as said plate can be made use of even for semiconductor wafers with different diameters.
